(19) United States
(12) Patent Application Publication
(10) Pub. No.: US 2007/0165884 A1
(43) Pub. Date: Jul. 19, 2007

(54) Information processing apparatus and sound control method therefor

(75) Inventor: Takahiro Nakazato, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Kabushiki Kaisha Toshiba

(21) Appl. No.: 11/655,417

(22) Filed: Jan. 19, 2007

(30) Foreign Application Priority Data
Jan. 13, 2006 (JP) P2006-22280

(51) Int. Cl. H02B 1/00; H03F 21/00

(52) U.S. Cl. 381/123; 381/120

(57) ABSTRACT

An information processing apparatus according to an embodiment of the present invention includes an amplifying unit configured to allow switching between a first gain characteristic and a second gain characteristic to be performed and a switching unit for performing switching between the first gain characteristic and the second gain characteristic. The first gain characteristic enables obtainment of a substantially linear input-output characteristic. The second gain characteristic has a gain higher than that of the first gain characteristic and enables obtainment of an input-output characteristic having a saturation characteristic.

### CROSS-REFERENCE TO RELATED APPLICATIONS

This application claims the benefit of priority of Japanese Patent Application No. 2006-22280, filed Jan. 31, 2006, the entire contents of which are incorporated herein by reference.

### BACKGROUND

1. Field

The present invention relates to information processing apparatuses and sound control methods therefor, and, more particularly, to an information processing apparatus containing a sound output device such as a speaker and a sound control method therefor.

2. Description of the Related Art

A sound output function has been realized for many information processing apparatuses such as a personal computer by having a sound output device such as a speaker contained therein. However, in known information processing apparatuses, an information processing function is regarded as a main function, and, the sound output function is only regarded as a subfunction.

On the other hand, information processing apparatuses having a high-quality digital TV broadcast receiving function and a DVD playback function of playing back a DVD, on which a high-quality image is recorded, are currently on the market. Accordingly, greater importance is attached to performance and quality in regard to an image display function and a sound output function in such information processing apparatuses.

With respect to the image display function, a high-resolution liquid crystal display is achieved, thereby enabling high-quality image display. However, with respect to the sound output function, the fact is that users' needs for both powerful and high-quality sound have not yet been satisfied partly because of physical constraints such as the constraint on the shape of an information processing apparatus.

As a technique for realizing the sound output function of an information processing apparatus, JP-A 9-55994 discloses a technique related to an acoustic device externally connected to an information processing apparatus. In this technique, when the acoustic device, to which a telephone line is connected, is used as a telephone receiver, the volume of a speaker provided for the acoustic device is set low, and, in other situations, normal volume is set.

Needs for a sound output function of an information processing apparatus include powerful sound and high-quality sound. For example, when users enjoy a game, etc. using an information processing apparatus such as a personal computer, there are needs for powerful and high-volume sound. On the other hand, when users enjoy music or a movie, there are needs for distortion-free and high-quality sound.

Volume control is a known example of a function of controlling volume in accordance with user's needs. Hardware or software volume control mechanism is a known way in which such a function of volume control can be implemented. The hardware volume control is performed, for example, by operating a volume dial disposed on the side surface of a personal computer. The software volume control is performed, for example, by dragging a slide bar on a menu screen.

By using the above-described volume control mechanism, a user can control sound to a certain degree so that high-volume sound can be output when enjoying a game, etc., and high-quality sound can be output when enjoying a movie or music.

More specifically, for example, the setting of the gain of a speaker amplifier is performed in advance so that the gain can be higher than a linear operating range (a nonlinear operation is performed) when volume is set to a maximum value. Consequently, when volume is set to the maximum value, although some sound distortions occur, high-volume sound can be obtained. On the other hand, if the gain of the speaker amplifier is reduced using the volume control mechanism, the gain falls within a linear operating range, whereby high-quality sound can be obtained.

However, the gain of the speaker amplifier is controlled by a user in this method. Accordingly, when the user desires high-quality sound reproduction, whether the gain of the speaker amplifier is controlled so that the gain can fall within a linear operating range is not necessarily secured. The reason is that the control by means of a volume dial or the like depends on the determination of the user who controls the gain of the speaker amplifier while listening to sound.

### SUMMARY OF THE INVENTION

The present invention has been made in view of the above-described background, and it is an object of the present invention to provide an information processing apparatus allowing a user to easily switch between a high-quality sound output function that secures a linear operation and a powerful and high-volume sound output function without performing a complicated operation, and provide a sound control method therefor.

An information processing apparatus according to an aspect of the present invention includes an amplifying unit configured to allow switching between a first gain characteristic and a second gain characteristic to be performed and a switching unit for performing switching between the first gain characteristic and the second gain characteristic. The first gain characteristic enables obtainment of a substantially linear input-output characteristic. The second gain characteristic has a gain higher than that of the first gain characteristic and enables obtainment of an input-output characteristic having a saturation characteristic.

An information processing apparatus according to another aspect of the present invention includes an audio codec unit, an amplifying unit, a switching unit, and a speaker unit. The audio codec unit generates an analog sound signal. The amplifying unit amplifies the analog sound signal generated by the audio codec unit in accordance with a gain characteristic. In addition, the amplifying unit is configured to allow switching between a first gain characteristic and a second gain characteristic to be performed. The first gain characteristic secures prevention of saturation occurrence even when a signal at a maximum level within an input range is input. The second gain characteristic shows a saturation characteristic when a signal at a level higher than a predetermined level is input and has a gain higher than that of the first gain characteristic. The switching unit performs switching between the first gain characteristic and the second gain characteristic. The speaker unit outputs sound on the basis of the analog sound signal that has been amplified by the amplifying unit in accordance with the gain characteristic changed by the switching unit.

A sound control method according to another aspect of the present invention is for an information processing apparatus that includes an output unit for outputting sound and an amplifying unit for amplifying a sound signal to be input into the output unit. The sound control method includes the steps of: (a) amplifying the sound signal in accordance with a first gain characteristic or a second gain characteristic and (b) switching between the first gain characteristic and the second gain characteristic. The first gain characteristic enables obtainment of a substantially linear input-output characteristic. The second gain characteristic has a gain higher than that of the first gain characteristic and enables obtainment of an input-output characteristic having a saturation characteristic.

According to the information processing apparatus and the sound control method therefor according to the aspects of the present invention, a user can easily switch between a high-quality sound output function that secures a linear operation and a powerful and high-volume sound output function without performing a complicated operation.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an exemplary external view of an information processing apparatus according to an embodiment of the present invention;

FIG. 2 is a diagram showing an exemplary system configuration of the information processing apparatus;

FIGS. 3A through 3D are diagrams showing an operational concept of a sound control method according to an embodiment of the present invention;

FIG. 4 is a flowchart showing an exemplary method of performing switching between a sound-quality-oriented mode and a sound-volume-oriented mode; and

FIGS. 5A and 5B are diagrams showing an operational concept of a sound control method according to an embodiment of the present invention.

### DETAILED DESCRIPTION

An information processing apparatus according to an embodiment of the present invention and a sound control method therefor will be described with reference to the accompanying drawings.

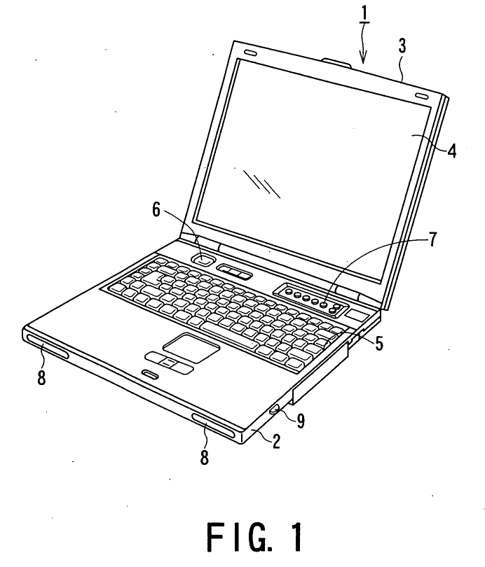

FIG. 1 is a diagram showing an external view of a notebook personal computer as a representative example of an information processing apparatus 1 according to an embodiment of the present invention.

The information processing apparatus 1 is provided with a thin and rectangular body section 2 and a panel section 3 openably and closably connected to the body section 2 via a hinge portion.

The body section 2 is provided on its upper surface with a keyboard 5 for inputting various pieces of data and instructing performance of various operations of the information processing apparatus 1, a power switch 6 for turning the information processing apparatus 1 on and off, and a sound mode button switch 7 for changing a sound mode.

Furthermore, the body section 2 is provided with speakers (a sound output unit) 8 for outputting the sound of music or a movie reproduced by the CD/DVD drive 23 at right and left positions on its front surface, and a sound volume controller (gain control unit) 9 for controlling the volume of sound to be output from the speakers 8 on its side surface.

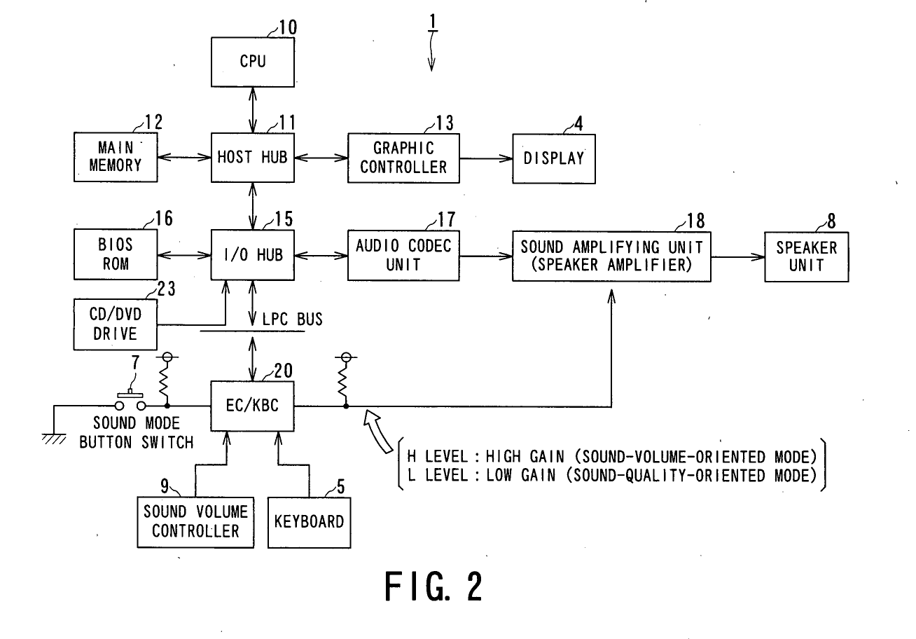

The body section 2 contains a system board on which electronic components such as a CPU 10 and a main memory 12 (see, FIG. 2) are disposed, and an external storage device such as a CD/DVD drive 23.

The panel section 3 is provided with a display 4 for displaying an image reproduced by the CD/DVD drive 23 and various information on its inner surface that is visible when the panel section 3 is in an open position. The display 4 is configured with, for example, a liquid crystal display. Furthermore, the body section 2 is provided with speakers (a sound output unit) 8 for outputting the sound of music or a movie reproduced by the CD/DVD drive 23 at right and left positions on its front surface, and a sound volume controller (gain control unit) 9 for controlling the volume of sound to be output from the speakers 8 on its side surface.

FIG. 2 is a block diagram showing an exemplary system configuration of the information processing apparatus 1. The information processing apparatus 1 is provided with the CPU 10 for controlling the whole system. The CPU 10 transmits or receives data to or from various internal components via a host hub 11 and an I/O hub 15.

The internal components provided for the information processing apparatus 1 include the main memory 12 for temporarily storing a program or data and functioning as a work area for the CPU 10, a BIOS ROM 16 for storing a BIOS, a graphic controller 13 for performing display control upon various pieces of image data, the display 4 for displaying an image, an audio codec unit 17 for demodulating sound data and converting the sound data to an analog sound signal, a sound amplifying unit (speaker amplifier) 18 for amplifying the analog sound signal, and the speakers (sound output unit) 8 for outputting sound.

The I/O hub 15 is connected to the CD/DVD drive 23 for playing back various pieces of image/video/sound content, and, in addition, is connected via an LPC (Low Pin Count) bus to an EC/KBC (Embedded Controller/KeyBoard Controller) 20 that is an embedded processor.

The EC/KBC 20 is connected to the keyboard 5, the sound mode button switch (switching unit) 7 for changing a sound mode, and the sound volume controller 9 for controlling the volume of the speakers 8.

An embodiment of the present invention is mainly related to the sound amplifying unit 18 and a sound control method therefor.

The image/video/sound content played back by the CD/DVD drive 23 includes music or movie content in which high-quality sound is provided and game content in which powerful and dynamic sound is provided. Generally, users attach importance to less-distorted and high-quality sound when listening to music or seeing a movie, on the other hand, attach importance to powerful and dynamic sound, that it, sound volume when playing a game.

The information processing apparatus 1 according to this embodiment and the sound control method therefor address such users' needs.

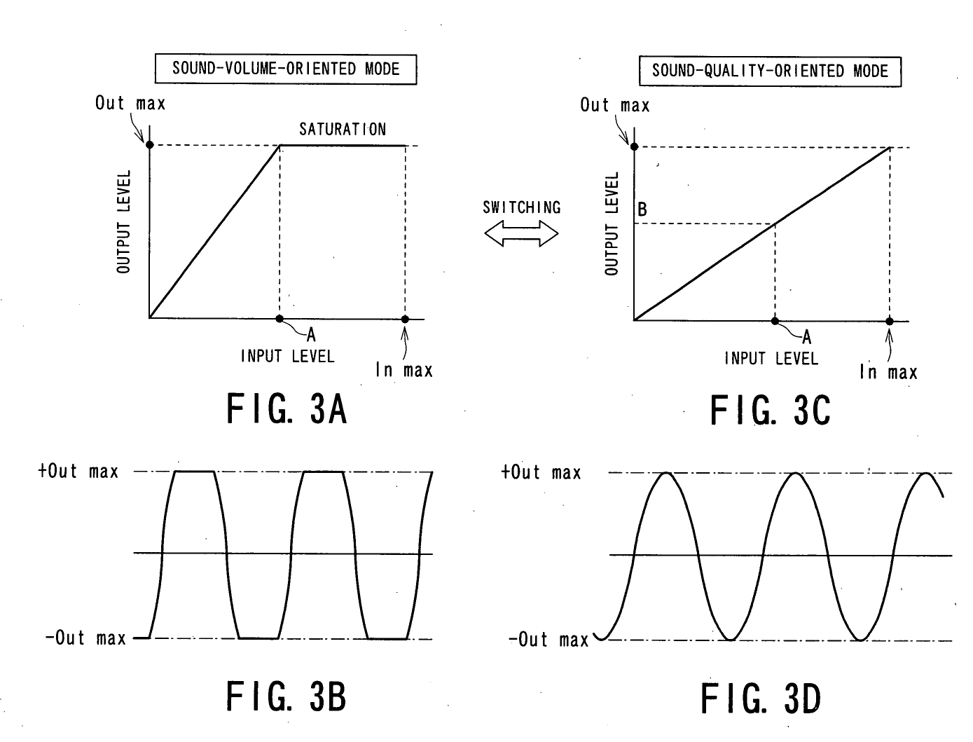

FIGS. 3A through 3D are diagrams showing exemplary input-output characteristics of the sound amplifying unit 18 according to this embodiment. The sound amplifying unit 18 has at least two different input-output characteristics corresponding to two sound modes (hereinafter referred to as a “sound-volume-oriented mode” and a “sound-quality-oriented mode”).

FIG. 3A shows the input-output characteristics corresponding to the sound-volume-oriented mode which enable output of high-volume sound. On the other hand, FIG. 3C shows the input-output characteristics corresponding to the sound-quality-oriented mode which enable output of less-distorted and high-quality sound.

In the input-output characteristics corresponding to the sound-quality-oriented mode shown in FIG. 3C, the gain of the sound amplifying unit 18 is set so that the sound amplifying unit 18 can operate within a linear region. Accordingly, even if a sound signal at a maximum input level In max is input into the sound amplifying unit 18, the number of occurrences of distortion can be reduced, and high-quality sound can therefore be obtained.

In contrast, in the input-output characteristics corresponding to the sound-volume-oriented mode shown in FIG. 3A, a gain higher than that of the input-output characteristics corresponding to the sound-quality-oriented mode is set. Accordingly, if a sound signal at the same input level is input into the sound amplifying unit 18 in each of these modes, the sound amplifying unit 18 can output higher-volume sound in the sound-volume-oriented mode compared with the sound-quality-oriented mode.

However, since the high gain is set in the sound-volume-oriented mode, if a sound signal at a level higher than a predetermined input level A is input, a saturation phenomenon occurs. This results in the occurrence of waveform distortion.

FIGS. 3B and 3D are diagrams schematically showing waveforms output when a sine wave at the maximum input level In max is input into the sound amplifying unit 18.

In an output waveform corresponding to the sound-quality-oriented mode (FIG. 3D), no waveform distortion occurs and an output waveform of a sine wave can be obtained. On the other hand, in an output waveform corresponding to the sound-volume-oriented mode (FIG. 3B), saturation occurs at a maximum output level Out max. This results in the occurrence of waveform distortion. However, from the viewpoint of sound volume, the average output level (effective value) of FIG. 3B is higher than that of FIG. 3D. Even if a sound signal at the maximum input level In max that causes saturation is input, the average volume of sound output in the sound-volume-oriented mode is higher than that of sound output in the sound-quality-oriented mode. Accordingly, in the sound-volume-oriented mode, the output of powerful sound can be expected.

If a sound signal at a level lower than the input level A (linear region in the sound-volume-oriented mode) is input, higher-volume sound can be output in the sound-volume-oriented mode, in which the high gain is set, compared with the sound-quality-oriented mode in accordance with a gain difference between these modes. For example, if a sound signal at the input level A is input, the output level of the sound-quality-oriented mode is a level B shown in FIG. 3C, on the other hand, the output level of the sound-volume-oriented mode can reach the maximum output level Out max.

Switching between the sound-volume-oriented mode and the sound-quality-oriented mode can be easily performed, for example, by pressing the sound mode button switch (switching unit: hardware switch) 7 disposed on the upper surface of the body section 2.

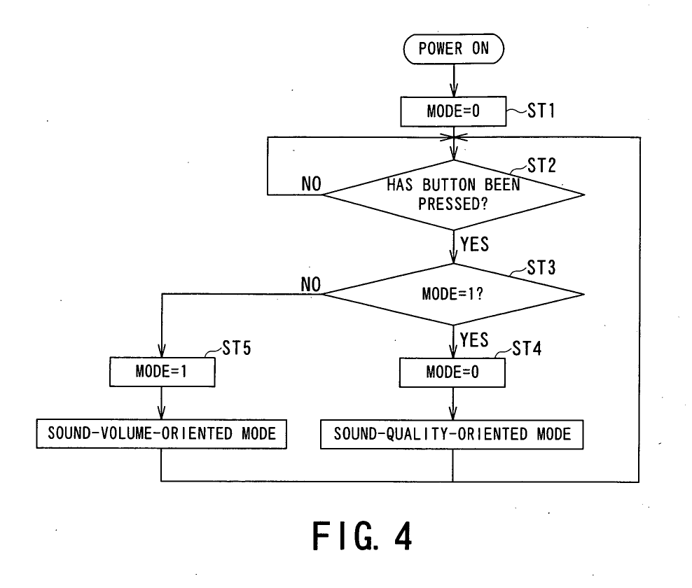

FIG. 4 is a flowchart showing this switching process.

In step ST1, a mode flag (MODE) is set to zero by default. Here, if the mode flag (MODE) is set to zero, the sound-quality-oriented mode is set, on the other hand, if the mode flag (MODE) is set to one, the sound-volume-oriented mode is set.

Next, in step ST2, whether the sound mode button switch 7 has been pressed is determined. As shown in FIG. 2, the contact signal of the sound mode button switch 7 is transmitted to the EC/KBC 20. The EC/KBC 20 determines whether the sound mode button switch 7 has been pressed using the transmitted contact signal.

If it is determined that the sound mode button switch 7 has been pressed, it is determined which sound mode is selected by monitoring the state of the mode flag (MODE) in step ST3. If the current sound mode is the sound-volume-oriented mode (MODE=1), the mode flag (MODE) is set to zero (is changed to the sound-quality-oriented mode) in step ST4. When the mode flag (MODE) is set to zero, a signal at an L level is transmitted to the sound amplifying unit 18 as shown in FIG. 2. Subsequently, the input-output characteristics of the sound amplifying unit 18 are changed from the sound-volume-oriented mode to the sound-quality-oriented mode.

On the other hand, if the current sound mode is the sound-quality-oriented mode (MODE=0) in step ST3, the mode flag (MODE) is set to one (is changed to the sound-volume-oriented mode). When the mode flag (MODE) is set to one, a signal at an H level is transmitted to the sound amplifying unit 18. Subsequently, the input-output characteristics of the sound amplifying unit 18 are changed from the sound-quality-oriented mode to the sound-volume-oriented mode.

Thus, the sound-quality-oriented mode and the sound-volume-oriented mode can be alternately switched between by simply pressing the sound mode button switch 7.

In the above-described description, although determination processing in steps ST2 and ST3 is performed by the EC/KBC 20, it may be performed by the CPU 10.

In addition, instead of or in combination with the operation of the sound mode button switch 7, a software switch (switching unit) may be used. In this case, a menu screen for sound mode switching is displayed on the display 4 under the control of the CPU 10, and is set so that the states of the mode flag (MODE) can be alternately changed, for example, with a mouse-click. Data on the mode flag (MODE) that has been set is transmitted to the EC/KBC 20. The transmitted data is converted into a signal at the H or L level by the EC/KBC 20, whereby the sound-volume-oriented mode and the sound-quality-oriented mode of the sound amplifying unit 18 can be alternately switched between.

The information processing apparatus 1 typically has a volume control mechanism in which sound volume is continuously or intermittently controlled. The volume of the speakers 8 can be continuously or intermittently controlled by operating the sound volume controller 9 disposed on the side surface of the body section 2. Alternatively, the volume can be controlled by dragging a volume slide bar displayed on a predetermined menu screen using a mouse or the like.

Such a volume control mechanism is achieved by causing the audio codec unit 17 to change a digital gain using software (to change a coefficient to be multiplied by sound data using software).

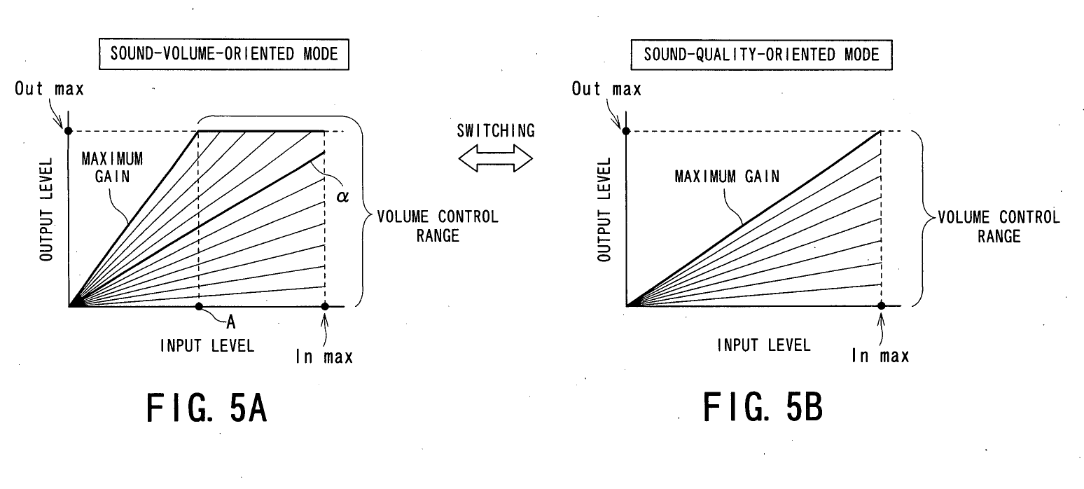

FIGS. 5A and 5B are diagrams illustrating input-output characteristics acquired by individually superimposing the above-described continuous or intermittent volume control characteristics on the input-output characteristics of the sound-volume-oriented mode and the input-output characteristics of the sound-quality-oriented mode.

In any input-output characteristics, the input-output characteristics shown in FIG. 3 represent a maximum gain, and the maximum gain is reduced by gain control performed by, for example, the sound volume controller 9.

In the sound-volume-oriented mode, the setting of a gain can be performed over a wide range from a very high gain to a low gain as shown in FIG. 5A. Accordingly, if the sound-volume-oriented mode is selected, the whole gain range of the sound-quality-oriented mode can be theoretically covered. In this case, when a user wants to enjoy powerful and high-volume sound, the user has only to set the maximum gain using the sound volume controller 9, and, when the user wants to enjoy distortion-free and high-quality sound of music or the like, the user has only to set the characteristics of a linear region, for example, characteristics α shown in FIG. 5A using the sound volume controller 9.

However, the continuous and intermittent volume control by means of the sound volume controller 9 depends on the user's sense of hearing. Accordingly, if the user tries to set the characteristics α in which the sound of a maximum volume level within the linear region can be output, the setting may not necessarily succeed. If the user has set a gain higher than the characteristics α, the user may not notice that fact. In this case, the user continues to listen to a slightly saturated (distorted) sound without noticing.

On the other hand, in the sound-quality-oriented mode, the characteristics of the linear region are always set irrespective of the operation of the sound volume controller 9. Accordingly, a user can always enjoy less-distorted and high-quality sound. Even if the user selects a maximum volume level using the sound volume controller 9 so as to set the volume level as high as possible, the sound amplifying unit 18 always operates within the linear region. Thus, the sound-quality-oriented mode indicates a mode that allows less-distorted sound to be output and secures an operation within a linear region.

As described previously, according to an information processing apparatus according to this embodiment and a sound control method therefor, a user can easily switch between a high-quality sound output function, in which a linear operation is secured, and a powerful and high-volume sound output function without performing a complicated operation.

The present invention is not limited to the above-described embodiment, and various modifications may be made without departing from the scope and spirit of the present invention when it is practiced. Various embodiments of the invention can be extracted by combining a plurality of components disclosed in the above-described embodiment. For example, some of all components described in the embodiment may be omitted. Furthermore, the components disclosed in different embodiments may be combined.

What is claimed is:

1. An information processing apparatus comprising:
an amplifying unit configured to allow switching between a first gain characteristic and a second gain characteristic to be performed, the first gain characteristic enabling obtainment of a substantially linear input-output characteristic, the second gain characteristic having a gain higher than that of the first gain characteristic and enabling obtainment of an input-output characteristic having a saturation characteristic; and
switching means for performing switching between the first gain characteristic and the second gain characteristic.

2. The information processing apparatus according to claim 1, further comprising controlling means for controlling the gain of the amplifying unit, and
wherein the first gain characteristic and the second gain characteristic are obtained when the controlling means controls the gain of the amplifying unit so that the gain can be a maximum value.

3. The information processing apparatus according to claim 1, wherein the switching means is a hardware switch.

4. An information processing apparatus comprising:
an audio codec unit for generating an analog sound signal;
an amplifying unit for amplifying the analog sound signal generated by the audio codec unit in accordance with a gain characteristic, the amplifying unit configured to allow switching between a first gain characteristic and a second gain characteristic to be performed, the first gain characteristic securing prevention of saturation occurrence even when a signal at a maximum level within an input range is input, the second gain characteristic showing a saturation characteristic when a signal at a level higher than a predetermined level is input and having a gain higher than that of the first gain characteristic;
switching means for performing switching between the first gain characteristic and the second gain characteristic; and
a speaker unit for outputting sound on the basis of the analog sound signal that has been amplified by the amplifying unit in accordance with the gain characteristic changed by the switching means.

5. The information processing apparatus according to claim 4, further comprising controlling means for continuously or intermittently controlling the gain of the amplifying unit; and
wherein the first gain characteristic and the second gain characteristic are obtained when the controlling means controls the gain of the amplifying unit so that the gain can be a maximum value.

6. The information processing apparatus according to claim 4, wherein the switching means is a hardware switch.

7. A sound control method for an information processing apparatus that includes an output unit for outputting sound and an amplifying unit for amplifying a sound signal to be input into the output unit, the sound control method comprising the steps of:
(a) amplifying the sound signal in accordance with a first gain characteristic or a second gain characteristic, the first gain characteristic enabling obtainment of a substantially linear input-output characteristic, the second gain characteristic having a gain higher than that of the first gain characteristic and enabling obtainment of an input-output characteristic having a saturation characteristic; and
(b) switching between the first gain characteristic and the second gain characteristic.

8. The sound control method according to claim 7, further comprising a step of (c) controlling the gain of the amplifying unit, and
wherein the first gain characteristic and the second gain characteristic are obtained when the gain of the amplifying unit is controlled in step (c) so that the gain can be a maximum value.

9. The sound control method according to claim 7, wherein switching between the first gain characteristic and the second gain characteristic is performed in step (b) using a hardware switch.
